(19) United States
(12) Patent Application Publication
(10) Pub. No.: US 2019/0156985 A1
(43) Pub. Date: May 23, 2019

(54) HIGH ACCURACY TUNING OF RESONANT NETWORK

(71) Applicant: Pi Inc., San Bruno, CA (US)

(72) Inventors: Nikola Popov, San Bruno, CA (US); Lixin Shi, Redwood City, CA (US)

(21) Appl. No.: 16/197,284

(22) Filed: Nov. 20, 2018

Related U.S. Application Data
(60) Provisional application No. 62/589,396, filed on Nov. 21, 2017.

(51) Int. Cl. H01F 27/24; H03J 3/02; H01F 27/28

(52) U.S. Cl. CPC H01F 27/24; H03J 3/02; H01F 27/42; H01F 2027/2819; H01F 27/2804

(57) ABSTRACT

A tunable inductor has a first magnetic core and a second magnetic core wound with a direct current (DC) winding and an alternating current (AC) winding. A first portion of the AC winding is wound around a first portion of the first magnetic core, and a second portion of the AC winding is wound around a first portion of the second magnetic core. The DC winding is wound simultaneously around the first magnetic core and the second magnetic core in a second portion that does not overlap the first portion of the first magnetic core and the second magnetic core. The DC winding is connected to a DC control circuit that applies a DC voltage to control permeability of the first magnetic core and the second magnetic core, which allows inductance value of the tunable inductor to be adjusted.

### CROSS-REFERENCE TO RELATED APPLICATIONS

The present application claims the benefit of U.S. Patent Application 62/589,396, which was filed Nov. 21, 2017, which is hereby incorporated by reference in its entirety.

### TECHNICAL FIELD

The disclosure relates to resonant network systems, and more particularly, to inductive charging systems.

### BACKGROUND

Many resonant networks rely on minimizing a reactive part of an overall load impedance for better coupling between a power transmitter and a power receiver. A lower impedance allows higher efficiency in a resonant network by permitting generation of a coupling magnetic field between a power transmitter and a power receiver using a lower supply voltage. An efficiency of the resonant network is represented by a quality factor (Q) that has an inverse relationship with reactance value such that a low reactance value corresponds to a high Q factor value (i.e., high efficiency). An example of high Q resonant network is wireless power transfer system. The overall size and volume of the wireless power transfer systems are inversely proportional to the magnetic field frequency, and therefore most of wireless power transfer systems use high-frequency coupling magnetic field to reduce the size of the wireless power transfer systems. However, the tradeoff for smaller size is that the environmental factors may have a more significant impact on the impedance at such a high frequency compared to large systems operating in a lower frequency domain. At high frequencies, the environmental factors can cause the reactance value of the system to shift, which can cause a large increase in the magnitude of the overall impedance. It is challenging to achieve the needed current in the power transmitter with a larger impedance using the same supply voltage. Thus, the efficiency in the coupling between the power transmitter and the power receiver is lower.

Common inductance values in the resonant network may be several tens of microhenries (μH) for inductance and several tens of picofarads (pF) for capacitance. Even a 1% of change of capacitance can increase the magnitude of the overall impedance by several times. Because environmental factors can cause a large variance in the reactance, achieving the needed current in the transmitter coil using the same supply voltage is challenging, and the system performance is degraded. Although adjusting the frequency to achieve the lowest reactance seems like an easy solution, usually it is not possible to fine-tune the frequency due to reasons such as the inability to synchronizing several different transmitter coils or even synchronizing transmitter and its corresponding receiver coils.

One way of minimizing the varying impedance in fixed-frequency systems is adding a switching capacitor network in the resonant circuit. By choosing an adequate switch (e.g., MOSFET) and capacitor combination, overall reactance can be minimized by controlling the frequency at which the switch changes states for a desired impedance value. However, these switching capacitor networks can produce discrete values instead of continuous values in resulting capacitance in the resonant circuit. Further, there is parasitic capacitance between drain and source of the switch that can introduce unwanted effects on the switching capacitor network. In addition, the finer the desired resolution, the more complex, bulky, and expensive the capacitive network.

### SUMMARY

A tunable inductor in a resonant circuit allows for continuous frequency tuning by adjusting a reactance of the tuning network in a power transmitter to match a resistance of a load in a power receiver. In one embodiment, the tunable inductor includes two magnetic cores (e.g., ferrite toroidal magnetic cores), an alternating current (AC) winding, and a direct current (DC) winding. The AC winding is a conductive wire where a first portion of the wire is wound around one of the magnetic cores in a first direction and a second portion of the wire is wound around the other magnetic core in a second direction that is opposite the first direction. The AC winding is connected to an AC circuit that applies AC voltage across the two ends of the AC winding. When voltage is applied, the opposite orientation of the first portion and the second portion in the AC winding generate magnetic fields in opposite directions that cancel each other out in the magnetic cores.

The DC winding is a conductive wire that is wound around both the first magnetic core and the second magnetic core such that the first magnetic core and the second magnetic core are equally biased. The DC winding is connected to a DC control circuit that applies DC voltage across the two terminals of the DC winding. The DC control circuit controls the magnetic field in the first magnetic core and the second magnetic core of the tunable inductor, which means that the permeability and overall reactance value of the tunable inductor may be adjusted. When the reactance value of the impedance is outside of an allowed range, the tuning network determines a phase angle between a voltage and a current in the resonant circuit and uses the phase angle to adjust the DC voltage supplied by the DC control circuit to maintain the reactance value within the allowed range. When the reactance value is within the allowed range, there may be more efficient and reliable coupling between the power transmitter and the power receiver.

### BRIEF DESCRIPTION OF THE DRAWINGS

Figure (FIG. 1 is a system diagram of a resonant network that includes a power transmitter and a power receiver, according to an embodiment.

FIG. 2 is a graph that describes the relationship between frequency and reactance, according to an embodiment.

FIG. 3 is an example of a tunable inductor with two magnetic cores, according to an embodiment.

FIG. 4 is a graph that describes the relationship between permeability and magnetic field in a magnetic core, according to an embodiment.

FIG. 5 is an example a stacked tunable inductor with two magnetic cores, according to an embodiment.

FIG. 6A is an example of an assembly of a stacked tunable inductor with two magnetic cores, according to an embodiment.

FIG. 6B is an example of a side view of stacked magnetic cores, according to an embodiment.

FIG. 7 is an example of a tunable inductor used with a printed circuit board (PCB), according to an embodiment.

FIG. 8 is an equivalent circuit of a tunable inductor, according to an embodiment.

FIG. 9 is an example of a power transmitter circuit that includes a tunable inductor, according to an embodiment.

FIG. 10 is a flow diagram of inductance tuning, according to an embodiment.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Minimizing or adjusting the reactive part of a load impedance is a common challenge for resonant networks. As such, resonant networks with reactance tuning is useful for different applications such as wireless communication systems, wireless charging systems, and magnetic resonance imaging (MM) systems. The resonant network 100 may be used in applications that use low frequencies in the kilohertz (kHz) range (e.g., resonant power converters, resonant transformers) as well as high frequency applications in the megahertz (MHz) range (e.g., magnetic resonance imaging (MRI)).

Figure (FIG. 1 is a system diagram of a resonant network 100 that includes a power receiver 110 and a power transmitter 120, according to an example embodiment. The power receiver 110 includes a load 112, a rectifier 114, an impedance matching unit 116, and a receiver coil 118. The power transmitter 120 includes a power amplifier 122, a resonant capacitor network 124, a tunable inductor network 126, a transmitter coil 128, a controller 130, and a measurement unit 132. In alternative embodiments, different and/or additional components may be included in the system.

The system shown in FIG. 1 is a conventional topology of wireless power transfer system. The power transmitter 120 is connected to a source of power (e.g., a power line) via the power amplifier 122 and converts the power to a time-varying electro-magnetic field. Energy stored in the electro-magnetic field in the transmitter coil 128 is received by the receiver coil 118 of the power receiver 110. The receiver 110 converts the received energy into electric current that is delivered to a load 112 of the power receiver 110.

The power amplifier 122 delivers an adequate amount of energy to the transmitter coil 128 of the power transmitter 120 such that enough electric current is available to the load 112 in the power receiver 110. The resonant capacitor network 124 and the tunable inductor network 126 minimize the reactance of the power transmitter 120 for efficient power transfer between the power transmitter 120 and the power receiver 110. Due to environmental impacts such as temperature variations or imperfections in components used in manufacturing the power transmitter 120, the overall impedance of the power transmitter 120 may increase. The resonant capacitor network 124, which includes at least one capacitor, may be used to adjust the reactance and minimize the overall impedance. The resonant capacitor network 124 may include a network of capacitors and switches (e.g., MOSFET) that open and close at a certain frequency to achieve a desired reactance. However, when the resonant network 100 is a high frequency system, the resonant network 124 requires a large network of capacitors and switches, which is bulky and expensive to manufacture. Further, the resonant capacitor network 124 can only introduce a discrete change of reactance instead of a continuous reactance value.

The tunable inductor network 126 that includes at least a tunable inductor can be used to continuously tune the reactance value and minimize the overall impedance of the power transmitter 120. The tunable inductor network 126 is cheaper to manufacture than a complicated resonant capacitor network 124 and allows for tuning the reactance with higher and continuous resolution than the resonant capacitor network 124 that can only make discrete adjustments.

The measurement unit 132 measures the phase angle between voltage across both the resonant capacitor network 124 and the tunable inductor network 126, and the current into the resonant capacitor network 124 and the tunable inductor network 126. The phase angle is subsequently used the controller 130 to decide if the system operates at resonant point.

The controller 130 takes the phase angle measurement from the measurement unit 132 and decide if we need to further tune the tunable inductor network 126 accordingly by controlling the DC voltage supply to the network. Specifically, if the phase angle is zero, the controller 130 does not change its DC output; if the phase angle is positive, which means voltage signal leads the current signal, it needs to increase the DC voltage to decrease the equivalent inductance of the tunable inductor network; and vice versa.

When the overall impedance is minimized, the power transmitter 120 transfers power to the power receiver 110 via magnetic coupling between the transmitter coil 128 and the receiver coil 118. The impedance matching unit 116 allows for optimal power delivery to the load 112, and the rectifier 114 converts the alternating current (AC) into direct current (DC) to drive the load 112.

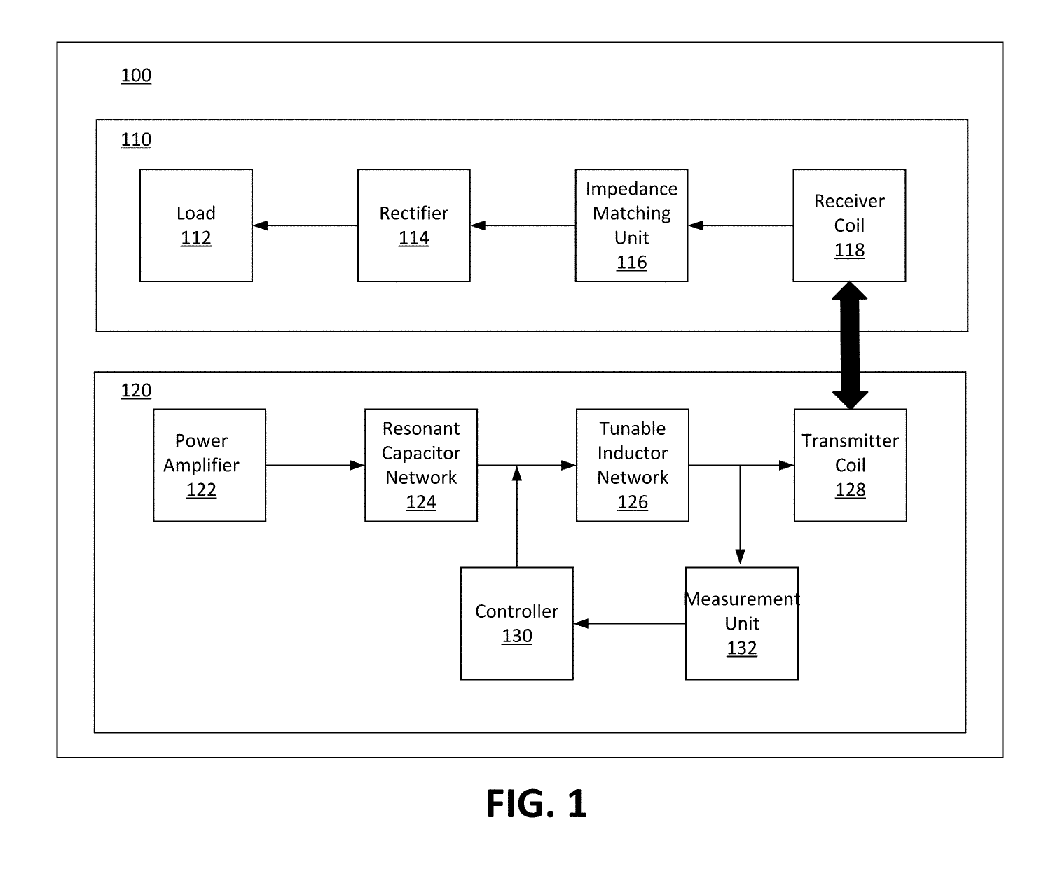

Referring now to FIG. 2, it is a graph that describes the relationship between frequency and reactance, according to an example embodiment. In the graph, the x-axis represents a frequency fin the MHz range and the y-axis represents a magnitude of impedance |Z| in the power transmitter 120. The different curves on the graph shows the shift that occurs with change in reactive parameters such as the capacitance value and the inductance value.

The value of R₀ represents a magnitude of impedance at an initial resonant frequency f₀ of 6.78 MHz when the power transmitter 120 has an initial inductance of L₀ and an initial capacitance of C₀ with no effects from the environment. Because at initial resonant frequency f₀, the inductor reactance and capacitor reactance cancel out, the magnitude of the impedance is only from resistance (e.g., R₀). However, when the inductance value decreases due to environmental impact, the magnitude of impedance increases at the initial resonant frequency f₀. For example, as shown in FIG. 2, when the inductance value decreases by 1% to 0.99L₀, the magnitude of impedance is about 1.3R₀ at the initial resonant frequency f₀. When the inductance value decreases by 2% to 0.98L₀, the magnitude of impedance is about 2R₀ at the initial resonant frequency f₀. When the inductance value decreases by 3% to 0.97L₀, the magnitude of impedance is about 5R₀ at the initial resonant frequency f₀.

Change in capacitance value also increases the overall magnitude of the impedance. When the capacitance value increases by 1% to 1.01C₀, the magnitude of impedance is about 1.3C₀. When the capacitance value increases by 2% to 1.02C₀, the magnitude of impedance is about 2R₀. When the capacitance value increases by 3%, the magnitude of impedance is about 2.8R₀.

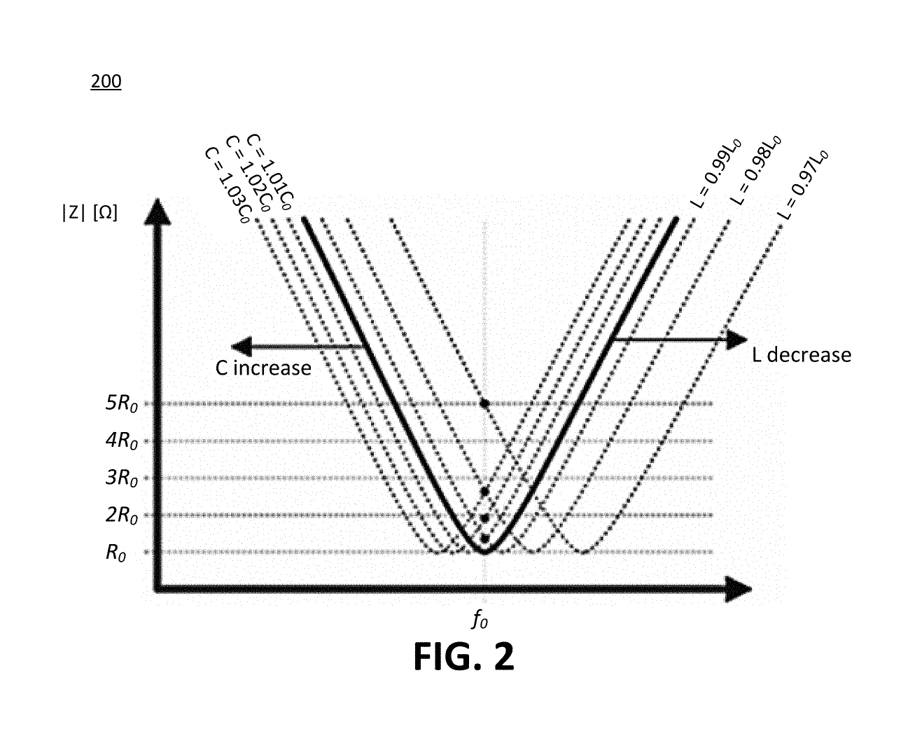

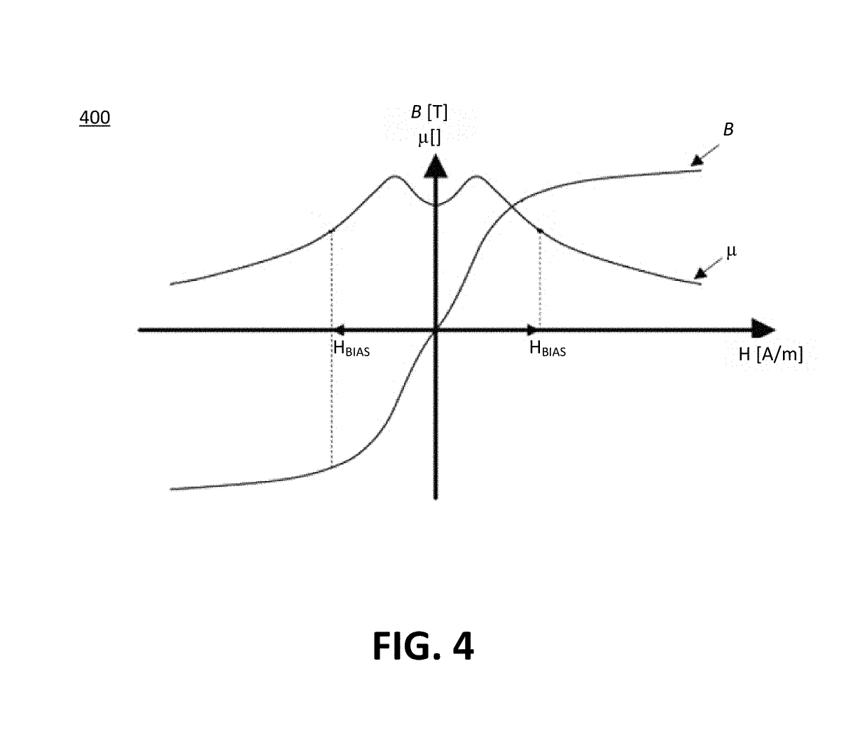

Turning now to FIG. 3, it is an example of a tunable inductor 300 with two magnetic cores, according to an example embodiment. The tunable inductor 300 is an “unwrapped” view of a “stacked” inductor 500 shown in FIG. 5. At a high level, it is noted that small changes in capacitance and inductance can cause large changes in the overall impedance for high frequency systems. Accordingly, overall impedance should be minimized to avoid power loss. The tunable inductor 300 has a variable inductance value, and the tunable inductor 300 may be controlled to have a particular inductance value to offset environmental effects on the impedance of a resonant circuit. Inductance depends on an inductor's geometry and on a permeability of a magnetic core of the inductor. For example, inductance of a coil wound around a core is given in Eq 1, where L is the inductance, N is the number of turns, l is the length of coil, μ is the permeability of the core, and A is the area of the core:

$$L = \frac{{N}^{2}}{\frac{l}{μ A}} \qquad Eq 1$$

The number of turns N, the length of the coil 1, and the area of the core A are physical traits of the inductor. These variables are fixed values in a given inductor. However, the permeability of a material varies as a function of magnetic field and may be adjusted to vary the value of an inductor. The magnetic field has a direct relationship with current and the permeability also varies as a function of current.

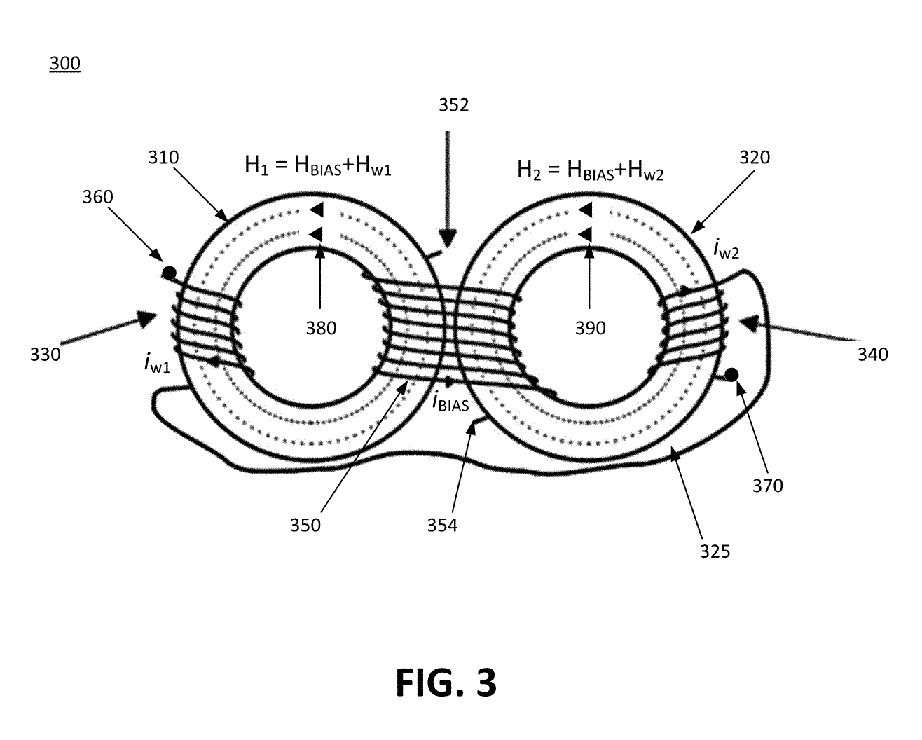

In FIG. 3, the illustrated tunable inductor 300 has a first core 310 and a second core 320. A first winding may be an alternating current (AC) winding 325 that includes a first portion 330 and a second portion 340. The first portion 330 includes a first terminal 360. The second portion 340 includes a second terminal 370. A second winding may be a direct current winding 350 that also includes a first terminal 352 and a second terminal 354. The first magnetic core 310 and the second magnetic core 320 are toroid magnetic cores that are made of a material that has a non-linear relationship between permeability and magnetic field, as discussed below with reference to FIG. 4.

FIG. 4 is a graph 400 that describes the relationship between permeability and magnetic field in a magnetic core using FIG. 3 as an example embodiment. The x axis of the graph 400 is a magnetic H-field with units of amperes per meter (A/m), and there are two curves shown with respect to the x axis: a B curve that represents a change in magnetic field in the magnetic core, and a μ curve that represents a change in permeability in the magnetic core.

A permeability of a material describes an ability of a magnetic material to support magnetic field development. When a material has a high permeability, the material is able to support a large magnetic field generated by a large current. As shown in FIG. 4, the permeability of the magnetic material increases when there is low magnetic H-field but decreases as the magnetic H-field increases until the permeability reaches a saturation level. Accordingly, as the magnetic H-field increases, the magnetic B-field in the magnetic core increases until reaching a plateau where the permeability reaches saturation.

Referring back to FIG. 3, the first magnetic core 310 is wound with a first portion of an AC winding 330, and the second magnetic core 320 is wound with a second portion of the AC winding 340. In some embodiments, the first portion 330 and the second portion 340 of the AC winding may be different portions of a unibody AC winding 325. In other embodiments, the first portion 330 and the second portion 340 of the AC winding 340 may be different wires that are electrically connected in series (e.g., soldered together). The first portion of the AC winding 330 is wound around a segment of the first magnetic core 310 in a first direction (e.g., clockwise) while the second portion of the AC winding 340 is wound around a segment of the second magnetic core 320 in a second direction that is opposite the first direction (e.g., counterclockwise).

A first terminal 360 of the first portion of the AC winding 330 and a second terminal 370 of the second portion of the AC winding 340 connect to an AC circuit. When the terminals are connected to a current source, a first alternating current (AC) i_{w1} flows through the first portion of the AC winding 330 and a second alternating current (AC) i_{w2} flows through the second portion of the AC winding 340. As the first portion 330 and the second portion 340 of the AC winding are connected, i_{w1} and i_{w2} are the same. In the first magnetic core 310, the first AC i_{w1} generates a first magnetic field H_{w1} in a first direction 380. In the second magnetic core 320, the second AC i_{w2} generates a second magnetic field H_{w2} in a second direction 390 that is opposite to the first direction because the second portion of the AC winding 340 is wound in the opposite direction of the first portion of the AC winding 330. As the first magnetic field H_{w1} and the second magnetic field H_{w2} are in opposite directions, they cancel each other out.

The structure of the tunable inductor 300 prevents both the first magnetic core 310 and the second magnetic core 320 from being saturated at the same time, which prevents power loss to heat and thereby improves efficiency. With the first portion of AC winding 330 and the second portion of AC winding 340 wound in opposite directions, when the first AC i_{w1} and the second AC i_{w2} are in positive half cycles, one of the first magnetic core 310 and the second magnetic core 320 are pushed closer to saturation level while the other is pushed away from saturation level. The tunable inductor 300 behaves symmetrically when the first AC i_{w1} and the second AC i_{w2} are in negative half cycles. The magnetic core that was pushed closer to saturation level in the positive half cycles is pushed away from the saturation level in the negative half cycles while the other magnetic core that was pushed away from saturation level in the negative half cycle is pushed towards the saturation level.

The first AC i_{w1} and the second AC i_{w2} are used to operate the resonant circuit and cannot be increased and decreased as needed to adjust the permeability of the first magnetic core 310 to adjust the overall inductance of the tunable inductor 300. Instead, there is a DC winding 350 that is used to bias the overall magnetic field (e.g., magnetic H-field) such that the permeability in the first magnetic core 310 and the second magnetic core 320 may be adjusted. The DC winding 350 is wound around both the first magnetic core 310 and the second magnetic core 320. Although not shown in FIG. 3, the DC winding 350 is connected to a DC circuit via its first terminal 352 and second terminal 354. The DC circuit (not shown) may include a DC voltage source that is adjusted based on required permeability in the magnetic cores. When the DC winding 350 is applied with the biasing DC voltage, the two magnetic cores are biased equally.

FIG. 5 is an example a stacked tunable inductor 500 with two magnetic cores, according to an example embodiment. The stacked tunable inductor 500 illustrates the tunable inductor (e.g., tunable inductor 300), that is modified such that the first magnetic core 310 is stacked on top of the second magnetic core 320. The first portion of the AC winding 330 is wound in the first direction around a segment of the first magnetic core 310 and the second portion of the AC winding 330 is wound in the second direction opposite the first direction around a portion of the second magnetic core 320. The number of windings in the first portion of the AC winding 330 is the same as the number of windings in the second portion of the AC winding 340. In some embodiments, the first portion 330 and the second portion 340 of the AC winding are made of a conductive unibody wire. In other embodiments, the first portion 330 and the second portion 340 are separate inductors that are electrically connected at a junction 380.

The DC winding 350 is wound around a top surface of the first magnetic core 310, side surfaces of the first magnetic core 310 and the second magnetic core 320, and a bottom surface of the second magnetic core 320. Because the DC winding 350 is the same for both the first magnetic core 310 and the second magnetic core 320, an equal DC bias may be applied to the two cores.

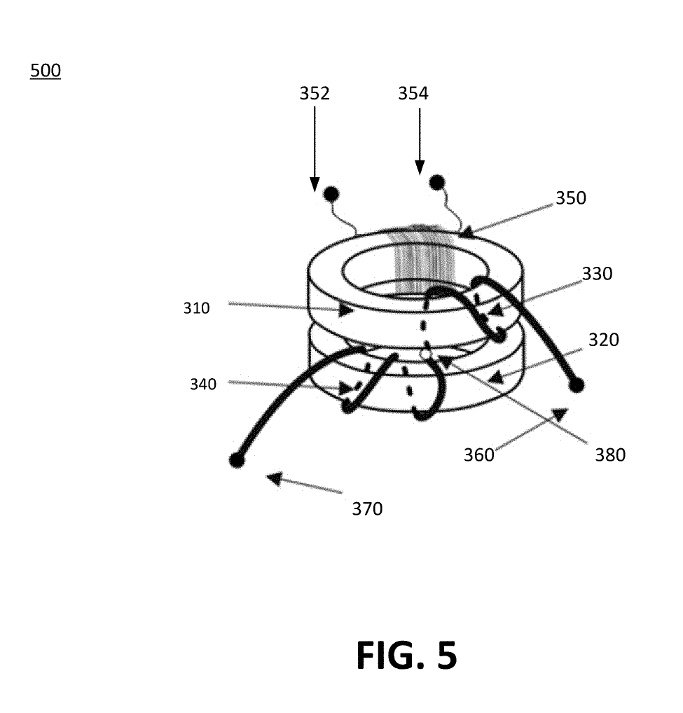

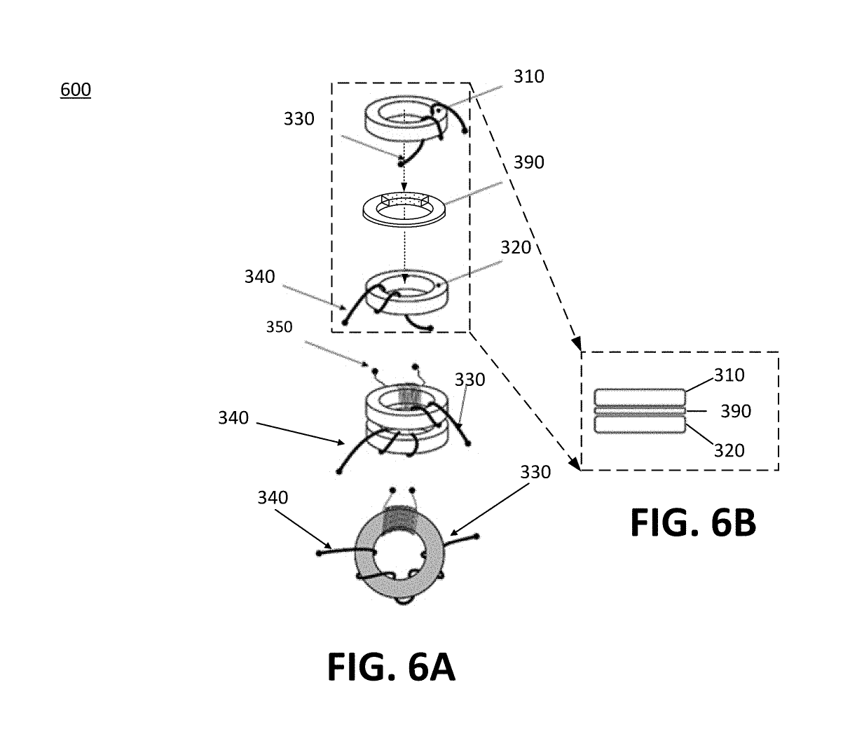

FIG. 6A is an example of an assembly 600 of a stacked tunable inductor with two magnetic cores, according to an embodiment. FIG. 6B is an example of a side view of stacked magnetic cores, according to an embodiment. The process described below may be may be for configuring the structure of FIG. 5.

In the example shown in FIG. 6A, the first magnetic core 310 is wound with the first portion of the AC winding 330 in a first direction, and the second magnetic core 320 is wound with the second portion of the AC winding 340 in a second direction. As shown in FIGS. 6A and 6B, an insulating layer 390 is inserted between the first magnetic core 310 and the second magnetic core 320 such that the two magnetic cores do not make contact with each other. The insulating layer 390 may be a segment of a ring and may be placed between a portion of the first magnetic core 310 and the second magnetic core 320 that does not overlap with portions of the cores that are wound with the AC winding such that there is space in between the first magnetic core 310 and the second magnetic core 320.

In some embodiments, the first portion of the AC winding 330 and the second portion of the AC winding 340 may be portions of a unibody wire. In other embodiments, the first portion of the AC winding 330 and the second portion of the AC winding 340 are made of separate wires. In this case, the first portion 330 and the second portion 340 of the AC winding may be electrically connected by soldering one end of the first portion 330 to one end of the second portion 340.

Once the AC winding is assembled, the DC winding 350 is wound simultaneously around the first magnetic core 310 and the second magnetic core 320. The DC winding 350 may be wound around any portion on the first magnetic core 310 and the second magnetic core 320. In some embodiments, it is preferred that DC winding 350 be wound around a portion of the first magnetic core 310 and the second magnetic core 320 such that the DC winding 350 does not overlap with any portion of the AC winding. When the DC winding 350 is overlapped with the AC winding, eddy currents may be induced in the DC winding due to the magnetic field generated by the AC winding, which may create additional power losses and lower efficiency. In the example shown in FIG. 6A, an end of the DC winding 350 is about 30 degrees apart from an end of the first portion of the AC winding 330, and another end of the DC winding 350 is about 30 degrees apart from an end of the second portion of the AC winding 340, with respect to the magnetic core.

In another example, the first magnetic core 310 and the second magnetic core 320 are stacked with the insulating layer 390 in between before windings are made. The stacked magnetic cores are simultaneously wound with the DC winding 350. Once the DC winding 350 is in place, the first portion 330 and the second portion 340 of the AC winding are wound around the stacked magnetic cores such that the first portion 330 and the second portion 340 are wound in opposite directions.

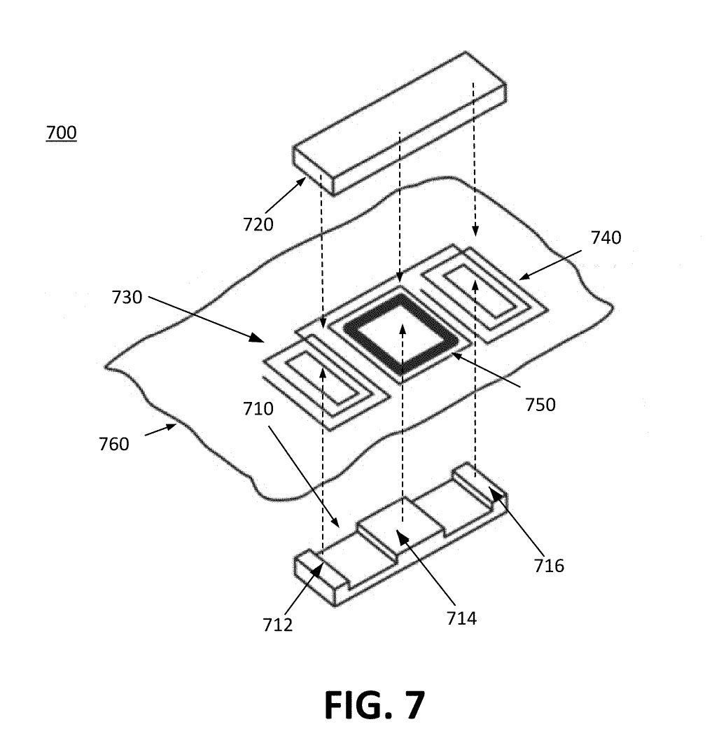

FIG. 7 is an example of a tunable inductor 700 used with a printed circuit board (PCB) 760, according to an example embodiment. The tunable inductor 700 includes a first magnetic core 710 and a second magnetic core 720 disposed on either surface of the PCB 760. The first magnetic core 710 may be an E-shaped magnetic core. The E-shaped magnetic core may have a unitary base with a first peak 712, a second peak 714, and a third peak 716 extending in a same direction. Each of the peaks may be separated from an adjacent peak by a valley. In some embodiments, the three peaks all have an equal width. In other embodiments, at least one of the peaks has a different width from the other two peaks. The two valleys separating the three peaks may be equal in width or different in width.

The second magnetic core 720 may be an I-shaped magnetic core which has a unitary base with a planar surface that makes contact with each of the peaks in the first magnetic core 710. The second magnetic core 720 may also be an E-shaped magnetic core that has the same shape as the first magnetic core 710 such that each peak of the first magnetic core 710 makes contact with a corresponding peak of the second magnetic core 720.

The PCB 760 is a substrate that includes at least three holes that allows the peaks of the first magnetic core 710 to pass through. Each hole corresponds to a peak of the first magnetic core 710, and the size of the hole depends at least on the width of the corresponding peak. The PCB 960 may be printed with a first portion of an AC winding 730, a second portion of the AC winding 740, and a DC winding 750 using a conductive material. The first portion of the AC winding 730 is printed around a hole corresponding to the first peak 112, and the second portion of the AC winding 740 is printed around a hole corresponding to the third peak 716 that are on either ends of the first magnetic core 710. The first portion of the AC winding 730 and the second portion of the AC winding 740 are electrically connected. The DC winding 750 is printed around a hole corresponding to the second peak 714 that is in between the first peak 712 and the second peak 716. The DC winding 750 does not make any contact with the first portion 730 or the second portion 740 of the AC winding.

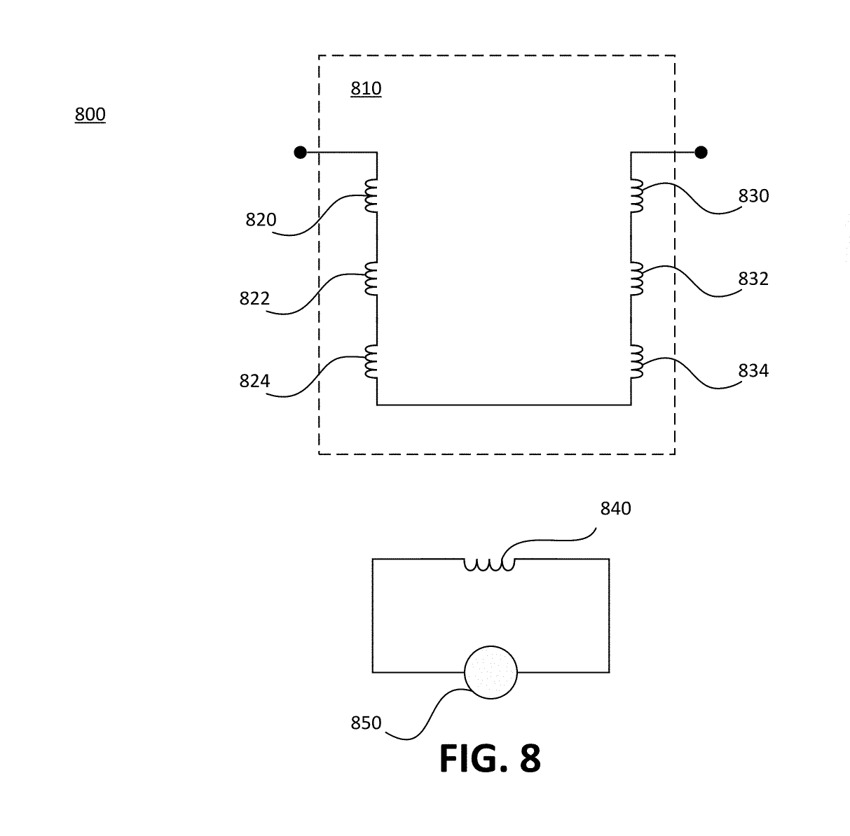

FIG. 8 is an equivalent circuit 800 of a tunable inductor, according to an embodiment. The equivalent circuit 800 may represent a tunable inductor with two toroid magnetic cores described with reference to FIGS. 3, 5, and 6 as well as a tunable inductor used with a PCB described with reference to FIG. 7. For simplicity, FIG. 8 is explained with reference to the tunable inductor with two toroid magnetic cores (e.g., FIG. 5) below.

The equivalent circuit 800 of the tunable inductor 500 has an AC part 810 and a DC part 840. The AC part 810 includes a first inductor 820, a second inductor 822, a third inductor 824, a fourth inductor 830, a fifth inductor 832, and a sixth inductor 834 that are connected in series. The first inductor 820, the second inductor 822, and the third inductor 824 are inductances in the top half of the tunable inductor shown in FIG. 5, and the fourth inductor 830, the fifth inductor 832, and the sixth inductor 834 are inductances in the bottom half of the tunable inductor shown in FIG. 5. The first inductor 820 represents inductance of the first portion of the AC winding 330 around the first magnetic core 310. The first inductor 820 is a combination of air core inductance of the first portion of the AC winding 330 and the added inductance due to unsaturated first magnetic core 310, which is controlled through the DC winding 350. The second inductor 822 represents a mutual inductance in the first portion of the AC winding 330 due to the second portion of the AC winding 340. The third inductor 824 represents a mutual inductance on the first portion of the AC winding 330 due to the DC winding 350. Similarly, the fourth inductor 830 is a combination of air core inductance of the second portion of the AC winding 340 and the added inductance due to unsaturated second magnetic core 320, which is controlled through the DC winding 350. The fifth inductor 832 represents a mutual inductance in the second portion of the AC winding 340 due to the first portion of the AC winding 330. The sixth inductor 834 represents a mutual inductance on the second portion of the AC winding 340 due to the DC winding 350.

The DC part 840 is connected to a DC voltage source 850. The DC voltage source outputs a stable DC voltage source to reduce voltage ripple. Although not shown in FIG. 8, there may be a capacitive filter across the DC part 840 to suppress noise. The DC part 840 represents a total mutual inductance due to the first portion of the AC winding 330 and the second portion of the AC winding 340.

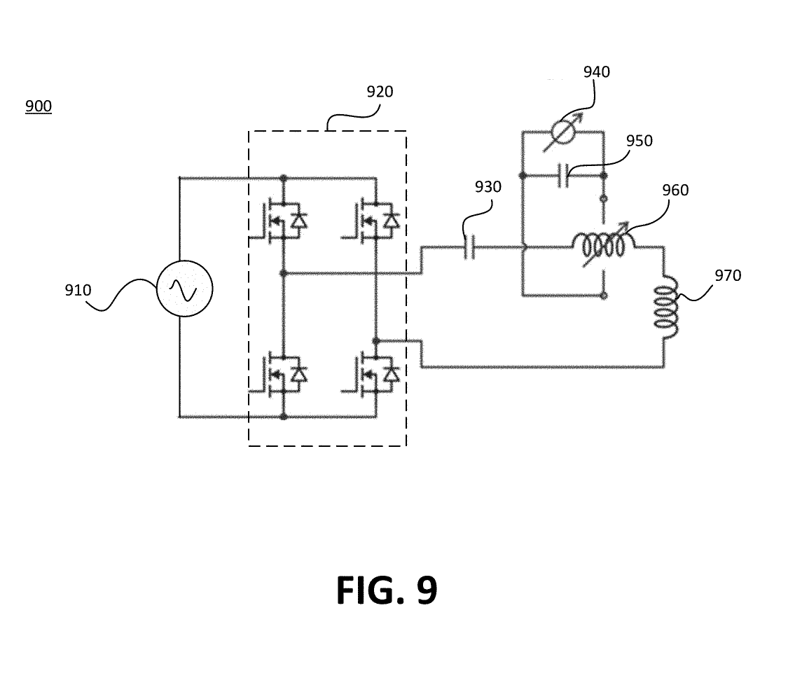

FIG. 9 is an example power transmitter circuit 900 that includes a tunable inductor 960, according to an example embodiment. The power transmitter circuit 900 is supplied with an AC power supply 910. The AC power supply 910 is connected to a H-bridge 920, which functions as a power amplifier to deliver enough energy to a transmitter coil 970. The H-bridge 920 is connected to a load which includes a resonant capacitor 930, a tunable inductor network including a DC voltage source 940, a capacitive filter 950, and the tunable inductor 960, and the transmitter coil 970. The DC voltage source 940 adjusts the bias voltage for tuning the tunable inductor 960. The capacitive filter 950 reduces noise in the tunable inductor network. The transmitter coil 970 couples to a receiver coil of a receiver (not shown) to transmit power to the receiver.

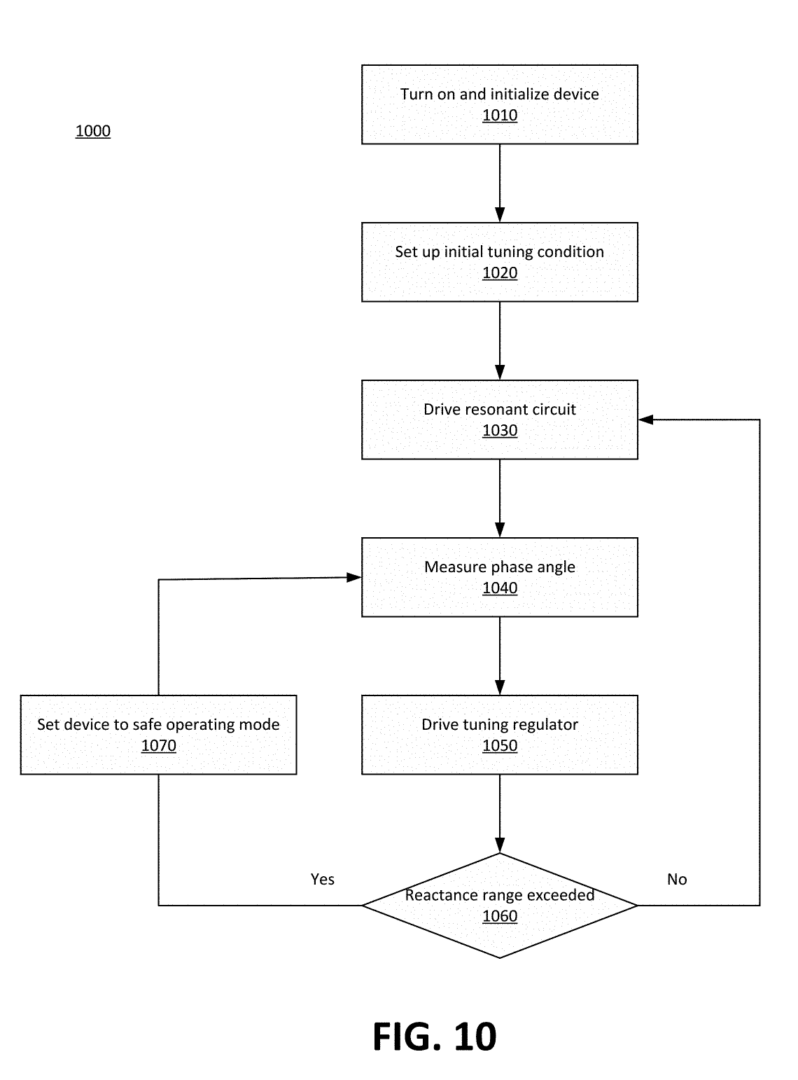

FIG. 10 is a flow chart 1000 of a tuning algorithm, according to an example embodiment. A device is turned on and initialized 1010. Once the device is on, an initial tuning condition is set up 1020. In some embodiments, the device is monitored by a system designer that manually sets the initial tuning conditions based on expected changes in impedance due to environment. In other embodiments, the device may be a personal device such as a wireless charger for a cellphone, and a prediction of initial tuning conditions may not be available. If initial tuning conditions are not available, a test phase measurement may be made such that an appropriate initial tuning condition may be calculated based on the test phase measurement.

Once initial tuning conditions are set, a resonant circuit is driven 1030 by applying an AC voltage at a certain frequency to the resonant circuit that includes at least a tunable inductor. After driving the resonant circuit, a phase angle between voltage and current in the resonant circuit is measured 1040. Based on the phase angle measurement, a tuning regulator is driven 1050 by applying a bias voltage to a DC winding of the tunable inductor.

After driving the tuning regulator 1050, it is determined whether reactance of the resonant circuit exceeds 1060 a desired range. If the reactance is outside of the desired range, the device is set 1070 to a safe operating mode. If the reactance is within the desired range, the device continues to operate in the regular feedback cycle.

The language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A tunable inductor comprising:
a first magnetic core;
a second magnetic core;
an alternating current (AC) winding, wherein a first portion of the AC winding is wound around the first magnetic core in a first direction, and a second portion of the AC winding is wound around the second magnetic core in a second direction that is opposite the first direction, the first portion and the second portion comprising a unibody wire; and
a direct current (DC) winding simultaneously wound around the first magnetic core and the second magnetic core.

2. The tunable inductor of claim 1, wherein the first portion of the AC winding is wound around a first segment of the first magnetic core, and the DC winding is wound around a second segment of the first magnetic core that does not overlap the first segment.

3. The tunable inductor of claim 1, wherein the second portion of the AC winding is wound around a first segment of the second magnetic core, and the DC winding is wound around a second segment of the second magnetic core that does not overlap the first segment.

4. The tunable inductor of claim 1, wherein the AC winding is connected to a circuit supplying an AC voltage.

5. The tunable inductor of claim 1, wherein the first magnetic core and the second magnetic core are ferrite toroidal magnetic cores.

6. The tunable inductor of claim 1, wherein the DC winding is connected to a DC control circuit supplying a DC voltage.

7. The tunable inductor of claim 1, wherein the first magnetic core and the second magnetic core are stacked.

8. The tunable inductor of claim 7, wherein the first magnetic core and the second magnetic core are separated via a insulating separater disposed in between the first magnetic core and the second magnetic core such that the first magnetic core and the second magnetic core are not in contact with each other.

9. A tunable inductor comprising:
a first magnetic core including a unitary base with three peaks extending in a same direction and two valleys separating each of the three peaks from an adjacent peak;
a second magnetic core configured to contact the three peaks of the first magnetic core;
an alternating current (AC) winding, wherein a first portion of the AC winding is wound around a first peak of the three peaks in a first direction, and a second portion of the AC winding is wound around a second peak of the three peaks in a second direction that is opposite the first direction, the first portion and the second portion electrically connected; and
a direct current (DC) winding wound around a third peak, the third peak located in between the first peak and the second peak.

10. The tunable inductor of claim 9, wherein the second magnetic core is a planar magnetic core.

11. The tunable inductor of claim 9, wherein the second magnetic core includes a unitary base with three peaks extending in a same direction and two valleys separating each of the three peaks from an adjacent peak.

12. The tunable inductor of claim 9, wherein the AC winding and the DC winding are printed on a printed circuit board.

13. The tunable inductor of claim 9, wherein the printed circuit board comprises at least a first opening, a second opening, and a third opening, each opening configured to receive one of the first peak, the second peak, and the third peak of the first magnetic core such that the AC winding is wound around the first peak and the second peak, and the DC winding is wound around the third peak.

14. The tunable inductor of claim 9, wherein the AC winding is connected to a circuit supplying an AC voltage.

15. The tunable inductor of claim 9, wherein the DC winding is connected to a DC control circuit supplying a DC voltage.

16. A tunable inductor comprising:
a first magnetic core;
a second magnetic core;
an alternating current (AC) winding, wherein a first portion of the AC winding is wound around a first segment of the first magnetic core in a first direction, and a second portion of the AC winding is wound around a first segment of the second magnetic core in a second direction that is opposite the first direction, the first portion and the second portion comprising a unibody wire; and
a direct current (DC) winding simultaneously wound around a second segment of the first magnetic core that does not overlap with the first segment of the first magnetic core and a second segment of the second magnetic core that does not overlap with the first segment of the second magnetic core.

17. The tunable inductor of claim 16, wherein an end of the first segment and an end of the second segment of the first magnetic core are separated by at least 30 degrees with respect to the first magnetic core.

18. The tunable inductor of claim 16, wherein the AC winding is connected to a circuit supplying an AC voltage.

19. The tunable inductor of claim 16, wherein the DC winding is connected to a DC control circuit supplying a DC voltage.

20. The tunable inductor of claim 16, wherein the first magnetic core and the second magnetic core are stacked.
